(19) United States
(12) Patent Application Publication
(10) Pub. No.: US 2014/0044889 A1
(43) Pub. Date: Feb. 13, 2014

(54) METHODS OF MAKING STRESSED MATERIAL LAYERS AND A SYSTEM FOR FORMING SUCH LAYERS

(71) Applicants: Yi Qi, Fishkill, NY (US); Chandra Reddy, Lagrangeville, NY (US)

(72) Inventors: Yi Qi, Fishkill, NY (US); Chandra Reddy, Lagrangeville, NY (US)

(73) Assignee: GLOBALFOUNDRIES INC., Grand Cayman (KY)

(21) Appl. No.: 13/571,604

(22) Filed: Aug. 10, 2012

(51) Int. Cl. C23C 14/28

(52) U.S. Cl. 427/595; 118/719

(57) ABSTRACT

Disclosed herein are various methods of making stressed material layers and a system for forming such layers. In one example, a deposition/irradiation system disclosed herein includes a process chamber, a wafer stage positioned within the process chamber, a deposition region and an irradiation region within the process chamber, wherein the system is adapted to separate the deposition region and the irradiation region by generating at least one isolating gas region between the deposition region and the irradiation region, means for supplying a precursor gas to the deposition region, means for supplying ultraviolet radiation to the irradiation region and means for supplying an isolation gas to the at least one isolating gas region.

### BACKGROUND OF THE INVENTION

1. Field of the Invention

Generally, the present disclosure relates to the manufacture of sophisticated semiconductor devices, and, more specifically, to various methods of making stressed material layers and a system for forming such layers.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein field effect transistors (NFET and PFET transistors) represent one important type of circuit element used in manufacturing such integrated circuit devices. A field effect transistor, irrespective of whether an NFET transistor or a PFET transistor is considered, typically comprises doped source and drain regions that are formed in a semiconducting substrate that are separated by a channel region. A gate insulation layer is positioned above the channel region and a conductive gate electrode is positioned above the gate insulation layer. By applying an appropriate voltage to the gate electrode, the channel region becomes conductive and current is allowed to flow from the source region to the drain region.

Device designers are under constant pressure to increase the operating speed and electrical performance of transistors and integrated circuit products that employ such transistors. Given that the gate length (the distance between the source and drain regions) on modern transistor devices may be approximately 30-50 nm, and that further scaling is anticipated in the future, device designers have employed a variety of techniques in an effort to improve device performance, e.g., the use of high-k dielectrics, the use of metal gate electrode structures, the incorporation of work function metals in the gate electrode structure and the use of channel stress engineering techniques on transistors (create a tensile stress in the channel region for NFET transistors and create a compressive stress in the channel region for PFET transistors). Stress engineering techniques typically involve the formation of specifically made silicon nitride layers that are selectively formed above appropriate transistors, i.e., a layer of silicon nitride that is intended to impart a tensile stress in the channel region of an NFET transistor would only be formed above the NFET transistors. Such selective formation may be accomplished by masking the PFET transistors and then blanket depositing the layer of silicon nitride, or by initially blanket depositing the layer of silicon nitride across the entire substrate and then performing an etching process to selectively remove the silicon nitride from above the PFET transistors. Conversely, for PFET transistors, a layer of silicon nitride that is intended to impart a compressive stress in the channel region of a PFET transistor is formed above the PFET transistors. The techniques employed in forming such nitride layers with the desired tensile or compressive stress are well known to those skilled in the art. Other stress engineering techniques involve forming cavities in the substrate adjacent the gate electrode and thereafter forming a stressed semiconductor material, typically silicon/germanium, in the cavities in an attempt to impart the desired stress to the channel region.

The manufacture of such stress-inducing silicon nitride layers typically involves performing an atomic layer deposition (ALD) process. In a first portion of the ALD process, a first precursor gas is introduced into the deposition chamber so as to form a mono-layer of material on the substrate. Any portions of the first precursor gas that are not absorbed on the substrate must then be purged from the process chamber. In the second portion of the ALD process, a second precursor gas is introduced into the deposition chamber so as to react with the existing mono-layer and thereby form the desired silicon nitride layer. However, such an ALD process is very time-consuming as the various gases are alternatively introduced into and purged from the ALD process chamber.

It is known that exposing silicon nitride films to ultraviolet (UV) radiation—so called UV curing—can enable the formation of silicon nitride films with very high tensile stress. The UV curing process involves removing the substrate from the ALD chamber and performing the UV curing process in a separate tool or chamber, i.e., an ex situ process, which slows production even further. Such ex situ UV curing processes may also cause variations in the properties of the material throughout its thickness if the layer is relatively thick. Another possible technique involves stopping the ALD process from time to time and shining a UV light source on the wafers. Such cyclic UV curing again takes more process time, and may also cause undesirable thickness variations in the final layer of silicon nitride.

The present disclosure is directed to various methods of making stressed material layers and a system for forming such layers.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of making stressed material layers and a system for forming such layers. In one example, a deposition/irradiation system disclosed herein includes a process chamber, a wafer stage positioned within the process chamber, a deposition region and an irradiation region within the process chamber, wherein the system is adapted to separate the deposition region and the irradiation region by generating at least one isolating gas region between the deposition region and the irradiation region, means for supplying a precursor gas to the deposition region, means for supplying ultraviolet radiation to the irradiation region and means for supplying an isolation gas to the at least one isolating gas region.

In another illustrative example, a method of forming a layer of material and UV curing the layer of material in a single process chamber comprises positioning a substrate on a moveable wafer stage positioned within the process chamber, performing a deposition process to form a layer of material above the substrate in a deposition region within the process chamber, after forming the layer of material, moving the wafer stage to position the substrate in an irradiation region within the process chamber and irradiating the layer of material with ultraviolet radiation using an irradiation means, wherein a portion of the irradiation means is positioned inside of the process chamber.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1E depict one illustrative embodiment of a system that may be employed herein to form stressed layers of material on semiconductor devices; and

FIG. 2A-2D depict one illustrative process flow wherein the methods disclosed herein are performed to form a stressed layer of material above a semiconductor device.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of making stressed material layers and a system for forming such layers. As will be readily apparent to those skilled in the art upon a complete reading of the present application, the presently disclosed methods and systems may be employed with a variety of technologies, e.g., NFET, PFET, CMOS, etc., and they may be readily employed in the manufacture of a variety of different layers of material on or above a variety of different devices or structures, including, but not limited to, semiconducting substrates, logic devices, memory devices, resistors, conductive lines, etc. With reference to the attached drawings, various illustrative embodiments of the methods and systems disclosed herein will now be described in more detail.

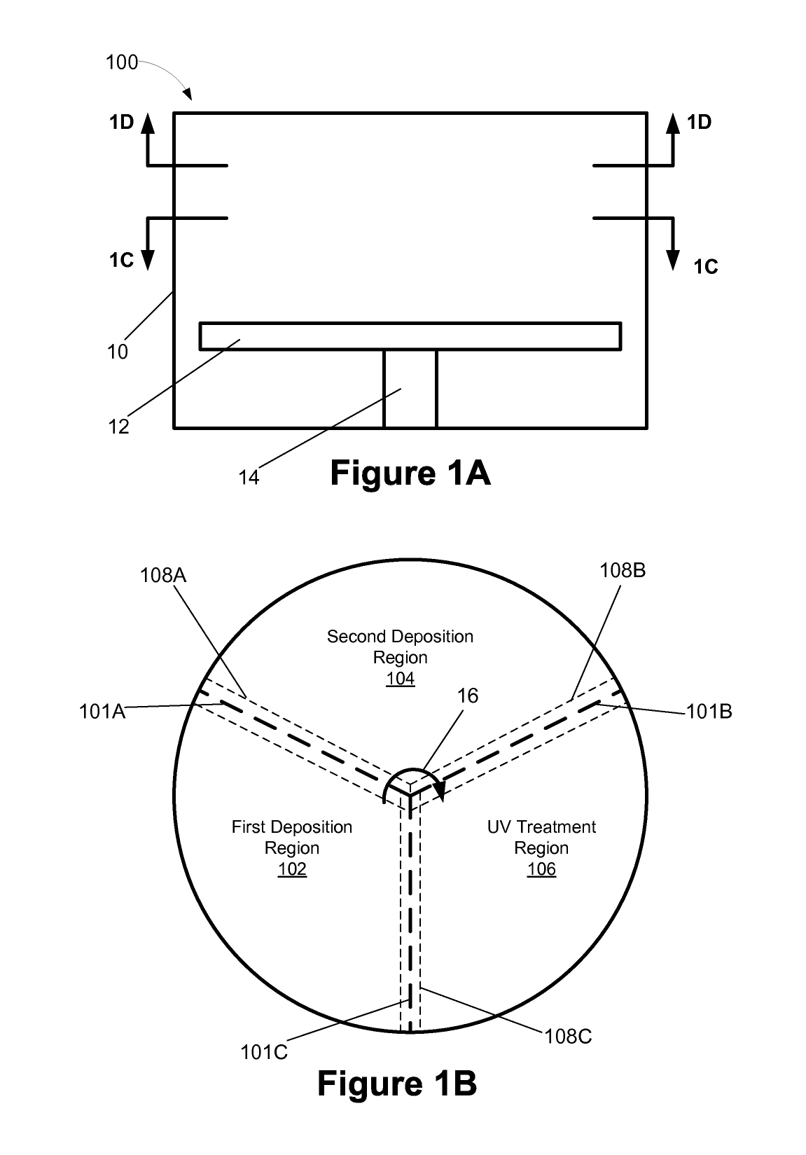

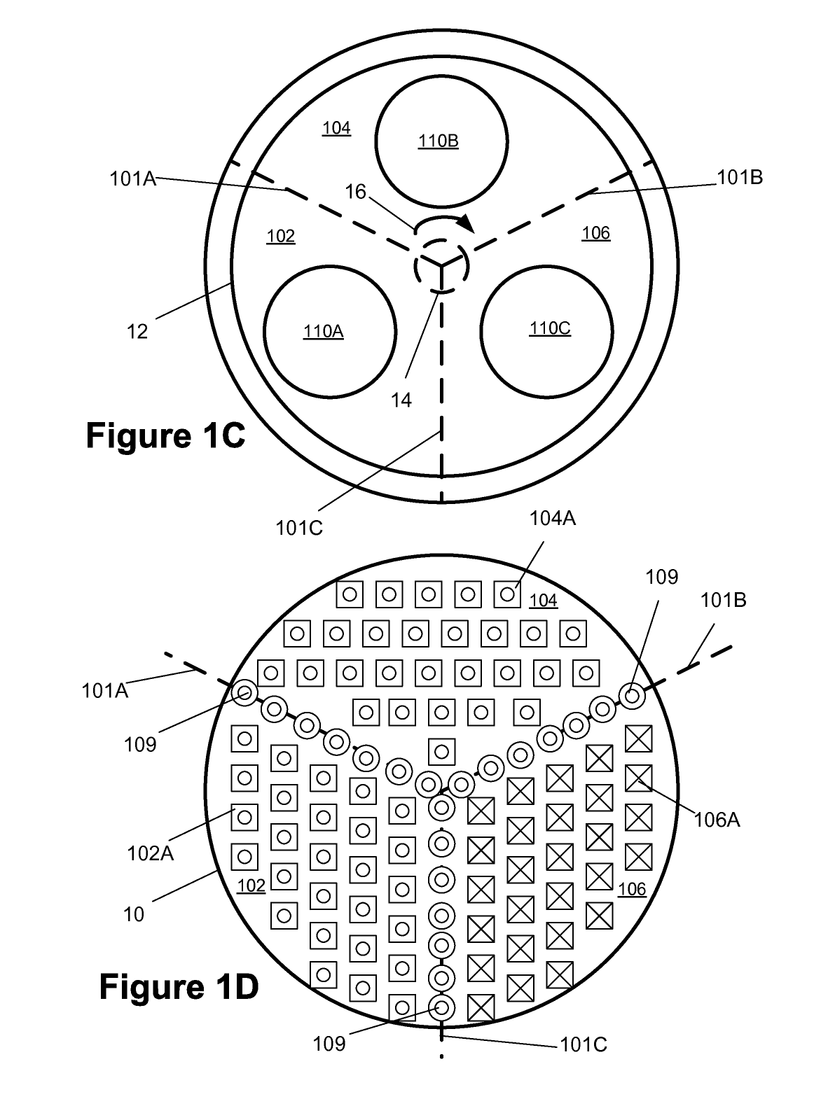

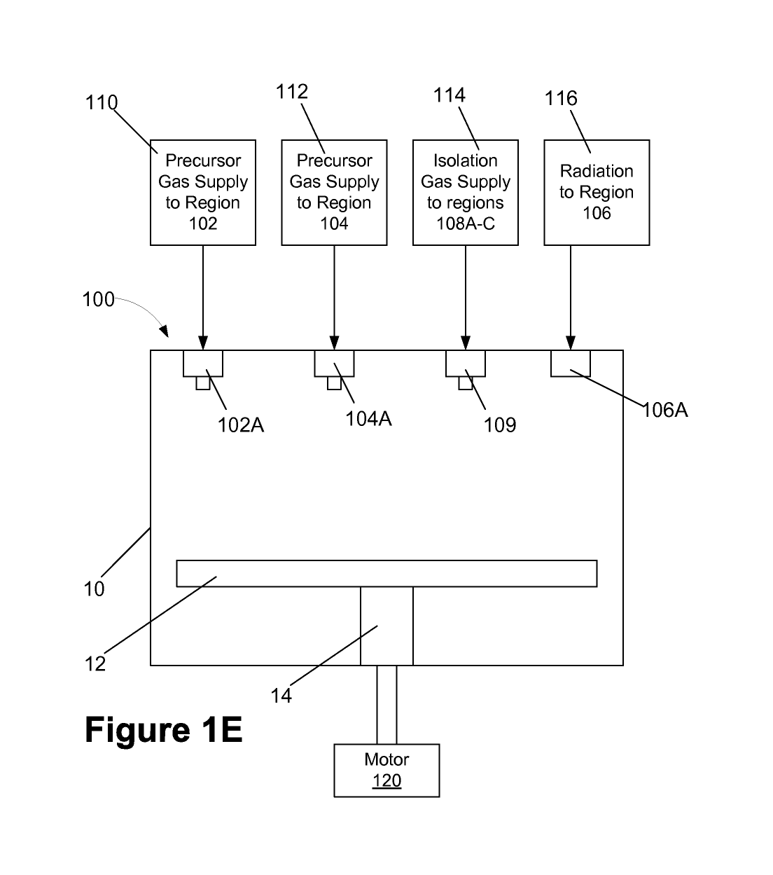

FIGS. 1A-1E schematically depict, in simplified form, various aspects of a deposition system 100 disclosed herein. In general, the system 100 is comprised of a process chamber 10 and a rotating wafer stage 12 that is adapted to hold one or more semiconducting substrates or wafers (not shown in FIG. 1A). The wafer stage 12 is adapted to rotate around an illustrative spindle 14. The wafer(s) may be operatively coupled to the wafer stage 12 by one or more mechanisms (not shown), such as clamping mechanisms, that are commonly employed in the semiconductor manufacturing industry.

With reference to FIG. 1B, various operational aspects of one illustrative embodiment of the deposition system 100 disclosed herein will now be discussed. In the depicted example, the process chamber 10 is effectively divided into three illustrative processing regions 102, 104, 106 by a plurality of isolating gas regions or curtains 108A-108C. In general, in one illustrative embodiment, the wafer stage 12 will be rotated in the direction 16 (see FIG. 1B) and substrates or wafers (not shown in FIG. 1B) will be sequentially processed in the segregated processing regions 102, 104 and 106, in situ, i.e., within the process chamber 10 without removal of the substrate from the chamber 10. In the depicted example, the system 100 comprises a first deposition region 102, a second deposition region 104 and an ultraviolet (UV) treatment region 106. In general, the isolating gas regions 108A-108C will be formed by flowing one or more non-forming gases, such as nitrogen or an inert gas that does not react, to effectively isolate the processing regions 102, 104, 106 from one another. As will be appreciated by those skilled in the art after a complete reading of the present application, the number, size and location of the separated process regions in such a deposition system 100 may vary depending upon the particular application and a variety of factors, such as the size of the process chamber 10, the number of wafers that may be positioned on the multi-wafer stage 12, etc. Thus, the illustrative depiction of three illustrative process regions should not be considered to be a limitation of the present invention.

The processing will be continued for as many cycles as desired to form a layer of material to a desired thickness above the substrates. Of course, in some cases, some of the illustrative process operation may not be performed in every cycle. For example, in some applications, the wafers processed in the system 100 may not be subjected to the UV treatment process (process region 106) every time a wafer is rotated through the first and/or second deposition regions 102/104. As will be recognized by those skilled in the art after a complete reading of the present application, the system 100 is schematic in nature, as any real-world deposition system 100 would include various electrical and mechanical features so that such a system could serve its intended function. For example, a real-world deposition system would likely include several valves, control instrumentation, one or more computers, inlets and outlets for various process gases, etc. Thus, the schematic depiction of the system 100 should not be understood to include all aspects of a real-world deposition system.

As indicated in FIG. 1A, FIG. 1C is a cross-sectional view looking down on the illustrative wafer stage 12. As shown in FIG. 1C, in the depicted example, the wafer stage 12 is adapted to hold three illustrative substrates 110A-C, although the system 100 and stage 12 may be adapted to process a lesser or greater number of substrates, e.g., one or more substrates. The physical size and shape of the substrates 110A-C may also vary.

As indicated in FIG. 1A, FIG. 1D is a cross-sectional view looking at the underside of the top of the process chamber 10. As shown in FIG. 1D, a plurality of nozzles and lamps may be employed to achieve the desired processing conditions within the process chamber 10. In the depicted example, the means for forming the isolating gas regions 108A-C comprises a plurality of schematically depicted nozzles 109. In the depicted example, the nozzles 109 are positioned along the lines 101A-C that define the approximate boundaries of each of the processing regions 102, 104, 106. Of course, the number, size and positioning of any nozzles that may be used in forming the isolating gas regions 108A-C may vary depending upon the particular application. For example, in some applications, the system 100 may include additional nozzles (not shown) that are arranged in a row positioned in the vertical wall of the chamber 10 and extending downward toward the wafer stage 12. The nozzles 109 are operatively coupled to a source of isolating gas 114, as schematically depicted in FIG. 1E, by various valves, piping and manifolds, etc., which are not depicted herein so as not to obscure the presently disclosed inventions. If necessary, the system 100 may also include a means for causing the flow of the desired quantity of such an isolating gas to the nozzles 109 at a desired pressure. If desired, different isolation gases, or combinations thereof, may be employed to separate different processing regions. In one illustrative embodiment, where the isolation gas is nitrogen, the nozzles may have a diameter of ¼ to ½ inch and the flow rate of nitrogen through each of the nozzles 109 may be on the order of about 100-1000 sccm, depending upon the number and size of the nozzles 109. Of course, instead of an arrangement of discrete nozzles 109, the isolation gas delivery system could take the form of an elongated slotted pipe or an elongated pipe with a plurality of openings therein. In an effort to insure that the non-forming isolation gases do not extend too far into the processing regions 102, 104, 106, the system 100 may have one or more vent lines (not shown) positioned under the wafer stage 12 and substantially aligned with the nozzles 109. Such vent lines may be in the form of elongated pipes positioned under the wafer stage 12 in substantial alignment with the nozzles 109. Such vent lines may be maintained at a slightly negative pressure relative to the pressure within the process chamber 10. Thus, the present invention should not be considered as limited to the illustrative examples of the isolation gas delivery system and its illustrative components depicted herein.

With continuing reference to FIG. 1D, the system 100 includes means for providing the desired precursor gases to the processing regions 102, 104. In the depicted example, the means for supplying the precursor gases to the regions 102, 104 comprises a plurality of schematically depicted nozzles 102A, 104A. That is, in the example depicted herein, a plurality of nozzles 102A are positioned above the first deposition region 102 and a plurality of nozzles 104A are positioned above the second deposition region 104. The nozzles 102A, 104A are operatively coupled to separate sources of precursor gases 110, 112, respectively, as schematically depicted in FIG. 1E, by various valves, piping and manifolds, etc., which are not depicted herein so as not to obscure the presently disclosed inventions. The size, number and arrangement of the nozzles 102A, 104A need not be the same, although that may be the case in some application. The nozzles 102A are adapted to deliver one or more precursor gases to the first deposition region 102 such that all or a portion of a layer of material may be formed above a substrate positioned within the region 102. Similarly, the nozzles 104A are adapted to deliver one or more precursor gases to the second deposition region 104 such that all or a portion of a layer of material may be formed above a substrate positioned within the region 104. Of course, the number, size and positioning of any of the nozzles 102A, 104A may vary depending upon the particular application. For example, in some applications, the region 102 may include additional inwardly-directed nozzles (not shown) that are arranged in one or more rows and columns positioned in the vertical wall of the chamber 10 (between the lines 101A and 101C) and extending downward toward the wafer stage 12. The region 104 may likewise include additional inwardly-directed nozzles (not shown) that are arranged in one or more rows and columns positioned in the vertical wall of the chamber 10 (between the lines 101A and 101B) and extending downward toward the wafer stage 12. If necessary, the system 100 may also include a means for causing the flow of the desired quantity of such precursor gases to the nozzles 102A, 104A at a desired pressure. Of course, instead of an arrangement of discrete nozzles 102A, 104A, the precursor gas delivery system for one or more of the regions 102, 104 could be provided in other forms. For example, instead of the discrete nozzles 102A, 104A, a plurality of slotted pipe or pipes with a plurality of openings therein could be employed. As another example, the precursor gas delivery system could take the form or one or more shower heads positioned within the processing regions 102, 104, or the precursor gas delivery system could employ a combination of mechanisms to insure adequate flow of precursor gases to the regions 102, 104, while providing adequate coverage of the wafer(s) processed within the regions 102, 104. In some cases, the precursor gas systems may share certain flow lines with appropriate purging as needed. Thus, the present inventions should not be considered as limited to the illustrative examples of the precursor gas delivery system and its illustrative components depicted herein.

With continuing reference to FIG. 1D, the system 100 includes means for providing UV radiation to the UV treatment region 106. In the depicted example, the means for providing such UV radiation includes a plurality of schematically depicted lamps 106A that are positioned above the UV treatment region 106. The lamps 106A are adapted to supply radiation at any desired wavelength (e.g., 100-500 nm) to the UV treatment region 106 so as to irradiate substrates positioned within the UV treatment region 106. The lamps 106A are operatively coupled to a radiation source 116, as schematically depicted in FIG. 1E. The size, number and arrangement of the lamps 106A may vary depending upon the particular application. For example, in some applications, the region 106 may include additional inwardly-directed lamps (not shown) that are arranged in one or more rows and columns positioned in the vertical wall of the chamber 10 (between the lines 101B and 101C) and extending downward toward the wafer stage 12. The lamps 106A are adapted to supply radiation to the UV treatment region 106 such that all or a portion of a layer of material previously formed above a substrate (in region 102/104) may be irradiated to change the properties of such a material layer, as described more fully below. In one example, exposing layers of material to such UV radiation tends to remove hydrogen and oxygen from the previously deposited layer of material. Thus, the present inventions should not be considered as limited to the illustrative examples of the means for providing radiation to the UV treatment region 106. The system 100 also includes an illustrative motor 120 for rotating the illustrative wafer stage 12. Of course, if desired, the wafer stage could be designed to simply translate from position to position within the process chamber 10.

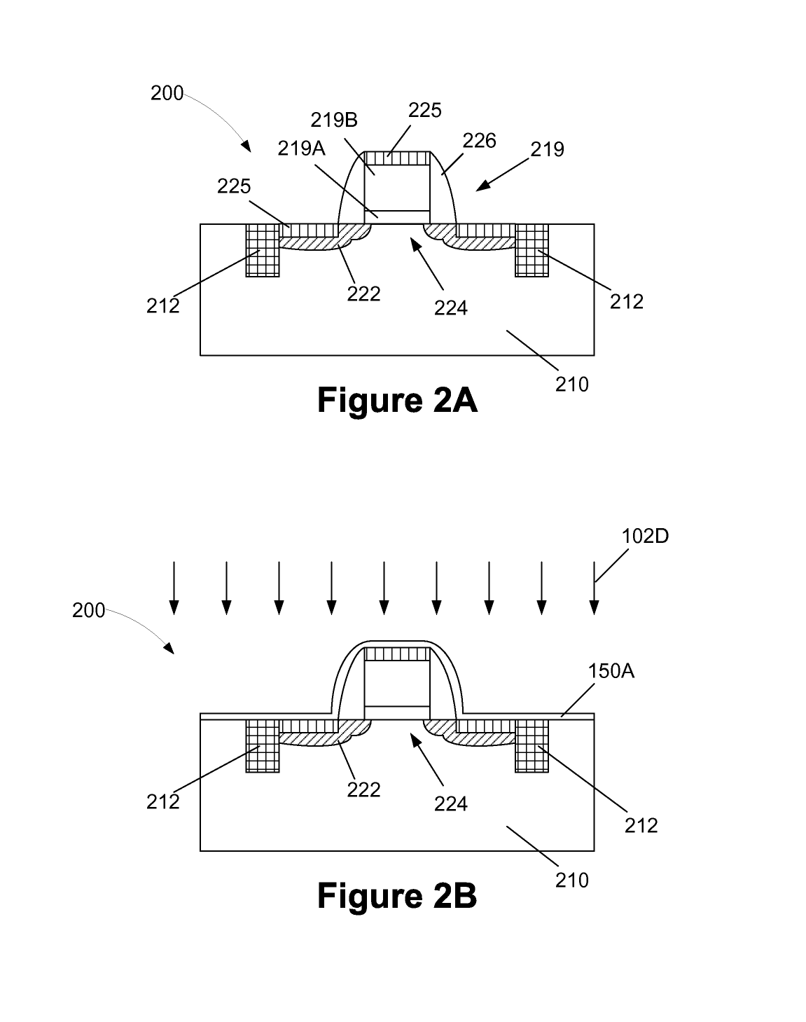

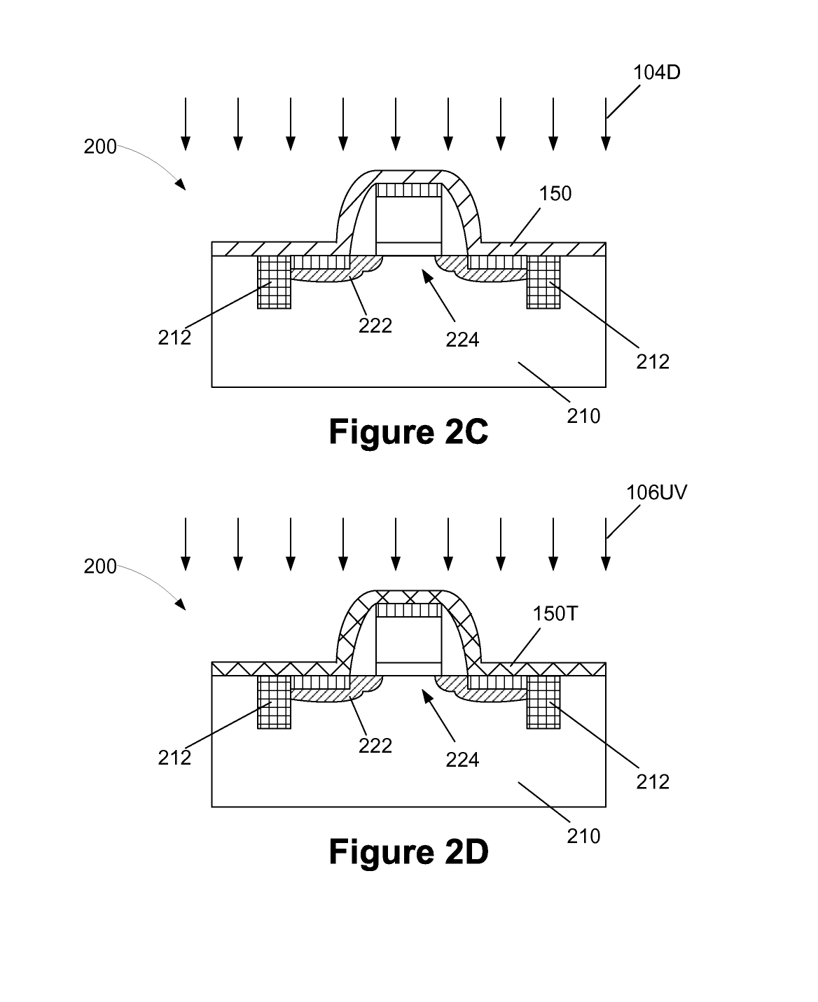

As described more fully below, the system 100 is adapted to form a variety of different stressed material layers, e.g., silicon nitride, silicon oxynitride, silicon dioxide, silicon carbon nitride, boron doped silicon nitride or silicon dioxide, etc. FIGS. 2A-2D depict one illustrative example wherein the system 100 is adapted to form a tensile stressed layer of silicon nitride above an illustrative NFET transistor 200. Of course, as will be recognized by those skilled in the art after a complete reading of the present application, the system disclosed herein may be employed to form different material layers having different stress properties (tensile, neutral or compressive) that may be employed for a variety of purposes on integrated circuit products. Thus, the present invention should not be considered to be limited to the illustrative example depicted in FIGS. 2A-2D.

FIG. 2A schematically depicts an illustrative NFET transistor 200 that is formed in and above an active region 224 defined in a semiconducting substrate 210 by a shallow trench isolation region 212. The transistor 200 is generally comprised of a gate structure 219 (comprised of a gate insulation layer 219A and a gate electrode 219B), sidewall spacers 226, a plurality of source/drain regions 222 and a plurality of metal silicide regions 225. In the illustrative example that follows below, the system 100 and process of using the system will be described in the context of forming a tensile-stressed layer of silicon nitride above the NFET transistor 200.

As shown in FIG. 2B, the nozzles 102A, 104A may have a diameter of ¼ to ½ inch. In such an example, the wafer is positioned within the first deposition region 102 by rotating the wafer stage 12 to the desired position or by simply loading the wafer in the desired position. Once properly positioned, a first deposition process 102D, such as an ALD process, is performed to form a first portion 150A of the silicon nitride layer above the transistor 200. During the first deposition process 102D, a first precursor gas, such as silane (SiH4), dichlorosilane (SiCl2) or disilane (Si2H6), is introduced into the first deposition region 102 through the plurality of nozzles 102A. The flow rate of such a first precursor gas may be on the order of about 10-100 sccm, depending upon the number and size of the nozzles 102A, as well as the desired thickness of the layer of silicon nitride. The flow of such a first precursor gas into the deposition region 102 may be pulsed or it may be continuous throughout the deposition process 102D.

As shown in FIG. 2C, after the first deposition process 102D is finished, the wafer stage 12 may be rotated so as to position the previously processed wafer (with the layer 150A formed thereon) within the second deposition region 104. In the second deposition region 104, a second deposition process 104D, such as an ALD process, is performed to complete the initial formation of the silicon nitride layer 150 above the transistor 200. During the second deposition process 104D, a second precursor gas, such as ammonium (NH4), is introduced into the second deposition region 104 via the nozzles 104A. In one example, the flow rate of the second precursor gas through each of the nozzles 104A may be on the order of about 10-100 sccm, depending upon the number and size of the nozzles 104A. The flow of such a second precursor gas into the deposition region 104 may be pulsed or it may be continuous throughout the deposition process 104D. The overall thickness of the layer of silicon nitride 150 may vary depending upon the particular application, e.g., it may have a thickness from about 1-500 nm.

As shown in FIG. 2D, after the second deposition process 104D is finished, the wafer stage 12 may be rotated so as to position the previously processed wafer (with the layer 150 formed thereon) within the UV treatment region 106. Thereafter, UV radiation 106UV is supplied to the UV treatment region 106, via the lamps 106A, at any desired wavelength (e.g., 100-500 nm) so as to irradiate the silicon nitride layer 150 (see FIG. 2C) and thereby transform the silicon nitride layer 150 into a UV-treated silicon nitride layer 150T, as indicated in FIG. 2D. The power density of the UV radiation process 106UV may vary depending upon a variety of factors such as, for example, the thickness and desired stress levels of the UV-treated silicon nitride layer 150T, the wavelength of the radiation used in irradiating the layer of silicon nitride 150, the rotation speed of spindle 14, etc. In one example, the duration of the UV radiation process 106UV may be on the order of about 1-20 W/cm². The UV radiation 106UV is adapted to change the properties of the original silicon nitride layer 150. More specifically, exposing the layer of silicon nitride 150 to such UV radiation tends to remove hydrogen and oxygen from the layer of silicon nitride 150, thereby resulting in the formation of the UV-treated silicon nitride layer 150T. In general, UV treatment of silicon nitride films has been shown to increase the amount of tensile stress that may be introduced into a layer of silicon nitride.

The above description of one illustrative process flow was made with reference to processing a single wafer through the system 100. However, as will be appreciated by those skilled in the art after a complete reading of the present application, the system 100 is adapted to process multiple wafers in parallel, thereby increasing production throughput, always a big concern in semiconductor manufacturing operations. For example, the first deposition process 102D, the second deposition process 104D and the irradiation process 106UV may all be performed more or less simultaneously (on separate wafers of course). After the completion of the last of the three process operations, the wafer stage 12 may be rotated or indexed and all three process operations 102D, 104D, 106UV may again be performed. In such an operating mode, throughput through the system 100 may be maximized. The throughput in such operating mode also depends on the rotating speed of spindle 14, which is mainly restricted by the mechanics of the system. In one example, the rotating speed of the spindle could be about 5-20 rpm.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A deposition/irradiation system, comprising:
a process chamber;
a wafer stage positioned within said process chamber;
a deposition region and an irradiation region within said process chamber, wherein said system is adapted to separate said deposition region and said irradiation region by generating at least one isolating gas region between said deposition region and said irradiation region;
means for supplying a precursor gas to said deposition region;
means for supplying ultraviolet radiation to said irradiation region; and
means for supplying an isolation gas to said at least one isolating gas region.

2. The system of claim 1, wherein said wafer stage is a rotatable wafer stage.

3. The system of claim 1, wherein said wafer stage is adapted to hold a plurality of semiconducting substrates as said substrates are processed in said process chamber.

4. The system of claim 1, wherein said deposition region is adapted to form at least a portion of a layer of silicon nitride, silicon dioxide, silicon oxynitride or doped versions of such materials that are doped with boron or carbon atoms above a semiconducting substrate positioned on said wafer stage.

5. The system of claim 1, wherein said means for supplying said precursor gas to said deposition region comprises a plurality of nozzles.

6. The system of claim 1, wherein said means for supplying said isolation gas to said isolation gas region comprises a plurality of nozzles.

7. The system of claim 1, wherein said means for supplying ultraviolet radiation to said irradiation region comprises a plurality of lamps.

8. A deposition/irradiation system, comprising:
a process chamber;
a rotatable wafer stage positioned within said process chamber, said rotatable wafer stage being adapted to hold a plurality of semiconducting substrates as said substrates are processed in said process chamber;
a first deposition region, a second deposition region and an irradiation region within said process chamber, wherein said system is adapted to separate said first deposition region, said second deposition region and said irradiation region from one another by generating at least one isolating gas region;
means for supplying a first precursor gas to said first deposition region;
means for supplying a second precursor gas to said second deposition region;
means for supplying ultraviolet radiation to said irradiation region; and
means for supplying at least one isolation gas to said at least one isolating gas region.

9. The system of claim 8, wherein said first deposition region is adapted to form a first portion of a layer of silicon nitride above a semiconducting substrate positioned on said wafer stage and said second deposition region is adapted to form a second portion of a layer of silicon nitride.

10. The system of claim 8, wherein said means for supplying ultraviolet radiation is adapted to supply ultraviolet radiation at a wavelength within the range of about 100-500 nm.

11. A method of forming a layer of material and UV curing the layer of material in a single process chamber, comprising:
positioning a substrate on a moveable wafer stage positioned within said process chamber;
performing a deposition process to form a layer of material above said substrate in a deposition region within said process chamber;
after forming said layer of material, moving said wafer stage to position said substrate in an irradiation region within said process chamber; and
irradiating said layer of material with ultraviolet radiation using an irradiation means, wherein a portion of said irradiation means is positioned inside of said process chamber.

12. The method of claim 11, wherein said deposition process is an atomic layer deposition process.

13. The method of claim 11, wherein said layer of material is comprised of one of silicon nitride, silicon dioxide and silicon oxynitride.

14. The method of claim 11, further comprising introducing at least one isolation gas into said process chamber to form at least one isolating gas region that separates said deposition region and said irradiation region.

15. The method of claim 11, wherein moving said wafer stage comprised rotating said wafer stage.

16. A method of forming a layer of material and UV curing the layer of material in a single process chamber, comprising:
positioning a substrate on a moveable wafer stage positioned within said process chamber;
performing a first deposition process to form a first portion of a layer of material above said substrate in a first deposition region within said process chamber;
after performing said first deposition process, moving said wafer stage to position said substrate in a second deposition region within said process chamber;
performing a second deposition process to form a second portion of said layer of material above said substrate in said second deposition region;
after performing said second deposition process, moving said wafer stage to position said substrate in an irradiation region within said process chamber; and
irradiating said layer of material with ultraviolet radiation in said irradiation region using an irradiation means, wherein a portion of said irradiation means is positioned inside of said process chamber.

17. The method of claim 16, wherein said first and second deposition processes are atomic layer deposition processes.

18. The method of claim 16, wherein said layer of material is comprised of one of silicon nitride, silicon dioxide and silicon oxynitride.

19. The method of claim 16, further comprising introducing at least one isolation gas into said process chamber to form at least one isolating gas region that separates said first deposition region, said second deposition region and said irradiation region from one another.

20. The method of claim 16, wherein moving said wafer stage comprises rotating said wafer stage.

21. A method, comprising:
positioning first, second and third substrates on a moveable wafer stage positioned within said process chamber, wherein said first substrate is positioned in a first deposition region within said process chamber, said second substrate is positioned in a second deposition region within said process chamber and said third substrate is positioned within an irradiation region within said process chamber;
prior to moving said moveable wafer stage:
performing a first deposition process to form a first portion of a layer of material above said first substrate;
performing a second deposition process to form a second portion of a second layer of material above said second substrate;
irradiating a third layer of material positioned above said third substrate with ultraviolet radiation in said irradiation region using an irradiation means, wherein a portion of said irradiation means is positioned inside of said process chamber; and
after irradiating said third layer of material, moving said wafer stage so as to move said first substrate to said second deposition region and to move said second substrate to said irradiation region.

22. The method of claim 21, further comprising introducing at least one isolation gas into said process chamber to form at least one isolating gas region that separates said first deposition region, said second deposition region and said irradiation region from one another.
